(19) United States
(12) Patent Application Publication
(10) Pub. No.: US 2007/0018300 A1
(43) Pub. Date: Jan. 25, 2007

(54) Apparatus and method for testing a multi-stack integrated circuit package

(75) Inventors: Jung-su Ryu, Seongnam-si (KR); Byeong-yun Kim, Seoul (KR); Yeon-keun Chung, Yongin-si (KR); Hyun-soo Park, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/481,937

(22) Filed: Jul. 7, 2006

(30) Foreign Application Priority Data
Jul. 7, 2005 (KR) 10-2005-0061243

(51) Int. Cl. H01L 23/02

(52) U.S. Cl. 257/686

(57) ABSTRACT

Provided is an apparatus and method for a testing multi-stack integrated circuit package. The apparatus may include a vacuum pump and a socket. The socket may include a plurality of internal pins, a plurality of external pins, a socket body, and at least one first air inlet. The plurality of external pins may be electrically connected to the plurality of internal pins. The at least one first air inlet may communicate with the atmosphere between the plurality of internal pins. When the multi-stack integrated circuit package including a plurality of packages is tested, a plurality of package pins of the multi-stack integrated circuit package may be inserted (or placed) into the plurality of internal pins of the socket. The multi-stack integrated circuit package may be pulled (or positioned) by applying a vacuum through the first air inlet of the socket using the vacuum pump.

### PRIORITY STATEMENT

This application claims the benefit of priority under 35 U.S.C. § 119 to Korean Patent Application No. 10-2005-0061243, filed on Jul. 7, 2005, in the Korean Intellectual Property Office (KIPO), the entire contents of which are incorporated herein by reference.

### BACKGROUND OF THE INVENTION

1. Field of the Invention

Example embodiments of the present invention relate to an apparatus for testing a multi-stack integrated circuit package. Other example embodiments of the present invention relate to a method for testing a multi-stack integrated circuit package.

2. Description of the Related Art

With increasing demand for higher storage capacity and/or faster operation speed of semiconductor integrated circuit devices, the impact of a package structure on the performance of an integrated circuit has become more important. Recently, a multi-stack package product, which has at least two stacked packages, has become available in order to increase the storage capacity of integrated chips.

FIG. 1 is a diagram illustrating a conventional apparatus 100 for testing a multi-stack integrated circuit package. The conventional apparatus 100 includes a socket 150 and a cover 160 of the socket 150. A multi-stack package 110 may be inserted into the socket 150. The multi-stack package 110 may include an upper package 120 and a lower package 130. Integrated chips 121 may be included in the upper package 120. An integrated chip 131 may be included in the lower package 130. Input/output pads 123 of the integrated chips 121 of the upper package 120 may connect to contact balls 140 through an upper substrate 122. The contact balls 140 may connect to the upper substrate 122. Input/output pads 123 of the integrated chip 131 of the lower package 130 may be connected to the contact balls 140 or package pins 133 via a lower substrate 132.

The package pins 133 of the multi-stack package 110 may be inserted into internal pins 151 of the socket 150. External pins 152 of the socket 150 may be connected to an external printed circuit board (PCB). The external pins 152 of the socket 150 may be connected to the internal pins 151 of the socket 150. The multi-stack package 110 may receive an input signal from the external PCB or transmit an output signal to the external PCB through the external pins 152.

To test the multi-stack package 110 using the conventional apparatus 100, the multi-stack package 110 may first be inserted into the socket 150 and the socket 150 may be covered with the cover 160. A pressing device 161 of the cover 160 may slightly press down the multi-stack package 110 for a desirable contact between the multi-stack package 110 and the internal pins 151 of the socket 150.

In such a conventional testing method, the contact quality of the contact balls 140 that electrically connect the upper substrate 122 of the upper package 120 and the lower substrate 132 of the lower package 130 may be altered. As a result, it may be difficult to determine if a crack occurs in the contact balls 140. It may also be difficult to assess the contact-quality between the upper substrate 122 and the lower substrate 132. By applying pressure to the contact balls 140 such that the contact balls 140 contact the upper substrate 122 and the lower substrate 132, contact failure may occur between the contact balls 140 and the upper substrate 122 or the contact balls 140 and the lower substrate 132. Contact failure may result from a crack of the contact balls 140 caused by shock. Contact failure may occur due to poor conductivity of a contact face between the upper substrate 122 and the lower substrate 132 or poor conductivity of the contact balls 140. The contact failure of the contact balls 140 may be removed by use of the pressing device 161 of the cover 160. As a result, the estimated contact quality may be different from the contact quality in an actual operation state. Thus, it may be difficult to determine if a crack exists in the contact balls 140. It also may be difficult to determine the crack is causing a contact failure between the contact balls 140 and the upper substrate 122 or the contact balls 140 and the lower substrate 132. Such a problem may also occur in a package structure having no cover 160.

### SUMMARY OF THE INVENTION

Example embodiments of the present invention relate to an apparatus for testing a multi-stack integrated circuit package. Other example embodiments of the present invention relate to a method for testing a multi-stack integrated circuit package.

Example embodiments of the present invention provide an apparatus for testing a multi-stack integrated circuit package wherein a failure caused by a contact ball may be more easily determined or assessed when the multi-stack integrated circuit package is inserted (or placed) into a socket for testing.

Other example embodiments of the present invention provide a method for testing a multi-stack integrated circuit package wherein a failure may be more easily determined and/or assessed.

According to example embodiments of the present invention, an apparatus may provide for testing a multi-stack integrated circuit package. The apparatus may include a vacuum pump and/or a socket. The socket may include a plurality of internal pins, a plurality of external pins, a socket body, and at least one first air inlet. The plurality of external pins may be electrically connected to the plurality of internal pins. The at least one first air inlet may be in communication with the atmosphere between the plurality of internal pins. When the multi-stack integrated circuit package including a plurality of packages is tested, a plurality of package pins of the multi-stack integrated circuit package may be inserted (or placed) into the plurality of internal pins. The multi-stack integrated circuit package may be pulled (or positioned) by suctioning the air, or applying a vacuum, through the at least one first air inlet using a vacuum pump.

In other example embodiments of the present invention, the multi-stack integrated circuit package may include an upper package and a lower package. Each package may include at least one integrated circuit chip and input/output pads of the upper package. The lower package may be electrically connected to a substrate of the upper package and a substrate of the lower package. The substrate of the upper and lower packages may be electrically connected by contact balls. The plurality of package pins of the multi-stack integrated circuit package may be electrically connected to the contact balls by the substrate of the lower package. The plurality of package pins may be electrically connected to input/output pads of the integrated circuit chip of the lower package by the substrate of the lower package. The bottom surface of the lower package may be pulled downward (or positioned) through air suction of the vacuum pump.

Example embodiments of the present invention provide a socket that may further include a cover portion on the upper package and at least one second air inlet for suctioning the air, or applying a vacuum, using the vacuum pump in the cover portion. The bottom surface of the lower package may be pulled downward (or positioned) and the top surface of the upper package may be pulled upward (or positioned) through air suction of the vacuum pump.

Example embodiments of the present invention provide an apparatus and method for testing a multi-stack integrated circuit package. The method may include inserting (or positioning) a plurality of package pins of a multi-stack integrated circuit package having a plurality of packages into a plurality of internal pins of a socket, pulling (or positioning) the multi-stack integrated circuit package by suctioning the air, or applying a vacuum, using a vacuum pump through at least one first air inlet (in communication with the atmosphere between the plurality of internal pins) located between the internal pins, applying (or transmitting) an input signal to test the multi-stack integrated circuit package from an external printed circuit board (PCB) through a plurality of external pins that may be electrically connected to the plurality of internal pins, and measuring an output signal of the multi-stack integrated circuit package.

### BRIEF DESCRIPTION OF THE DRAWINGS

Example embodiments of the present invention will be more clearly understood from the following detailed description taken in conjunction with the accompanying drawings. FIGS. 1-4 represent non-limiting, example embodiments of the present invention as described herein.

FIG. 1 is a diagram illustrating a conventional apparatus for testing a multi-stack integrated circuit package;

FIG. 2 is a diagram illustrating an apparatus for testing a multi-stack integrated circuit package according to example embodiments of the present invention;

FIG. 3 is a diagram illustrating an apparatus for testing a multi-stack integrated circuit package according to example embodiments of the present invention; and

FIG. 4 is a diagram illustrating a contact failure.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”“includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Also, the use of the words “compound,” “compounds,” or “compound(s),” refer to either a single compound or to a plurality of compounds. These words are used to denote one or more compounds but may also just indicate a single compound.

Now, in order to more specifically describe example embodiments of the present invention, various embodiments of the present invention will be described in detail with reference to the attached drawings. However, the present invention is not limited to the example embodiments, but may be embodied in various forms. In the figures, if a layer is formed on another layer or a substrate, it means that the layer is directly formed on another layer or a substrate, or that a third layer is interposed there between. In the following description, the same reference numerals denote the same elements.

Although the example embodiments of the present invention have been disclosed for illustrative purposes, those skilled in the art will appreciate that various modifications, additions and substitutions are possible, without departing from the scope and spirit of the invention as disclosed in the accompanying claims.

Hereinafter, the present invention will be described in detail by explaining example embodiments of the invention with reference to the attached drawings, wherein like reference numerals refer to the like elements throughout.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Example embodiments of the present invention relate to an apparatus for testing a multi-stack integrated circuit package. Other example embodiments of the present invention relate to a method for testing a multi-stack integrated circuit package.

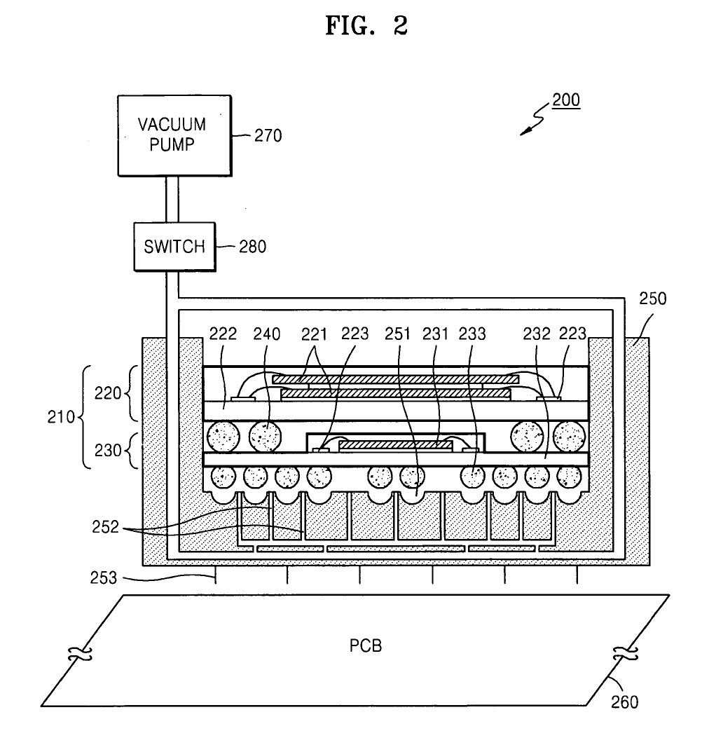

FIG. 2 is a diagram illustrating an apparatus 200 for testing a multi-stack integrated circuit package 210 according to example embodiments of the present invention.

Referring to FIG. 2, the apparatus 200 may include a socket 250, a vacuum pump 270, and a switch 280. For the convenience of explanation, an external printed circuit board (PCB) 260 is also illustrated.

The multi-stack integrated circuit package 210 may include an upper package 220 and a lower package 230. Integrated circuit chips 221 may be included in the upper package 220. An integrated circuit chip 231 may be included in the lower package 230.

Although the multi-stack integrated circuit package 210 includes two packages 220 and 230 in FIG. 2, the multi-stack integrated circuit package according to example embodiments of the present invention may include more than two packages. Although the upper package 220 and the lower package 230 includes two integrated circuit chips and one integrated circuit chip, respectively, the upper and lower packages 220/230 may include at least one integrated circuit chip.

The integrated circuit chips 221 and 231 of the upper package 220 and the lower package 230, respectively, may have signal input/output pads 223. Upper signal input/output pads of the integrated circuit chips 221 of the upper package 220 may be connected to contact balls 240 by an upper substrate 222. Lower signal input/output pads of the integrated circuit chip 231 of the lower package 230 may be connected to the contact balls 240 or a plurality of package pins 233 of the multi-stack integrated circuit package 210 by a lower substrate 232. The plurality of package pins 233 may be electrically connected to the contact balls 240. The plurality of package pins 233 may also be electrically connected to the signal input/output pads 223 of the integrated circuit chip 231 of the lower package 230 by the substrate 232 of the lower package 230. The plurality of package pins 233 may input and output signals.

The socket 250 may include a socket body, a plurality of internal pins 251 and a plurality of external pins 253. The plurality of external pins 253 may be electrically connected to the plurality of internal pins 251. At least one air inlet 252 may be in communication with the atmosphere between the internal pins 251.

For testing purposes, the package pins 233 of the multi-stack integrated circuit package 210 may be inserted (or placed) into the internal pins 251 of the socket 250. The external pins 253 of the socket 250 may be connected to the external PCB 260.

Before input/output signals of the multi-stack integrated circuit package 210 are measured, the switch 280 may be turned on. The air may be suctioning the air, or applying a vacuum, through the air inlet 252 of the socket 250 by the vacuum pump 270 by turning on the switch 280. The bottom surface of the lower package 230 may be pulled downward (or positioned) by the air suction of the vacuum pump 270.

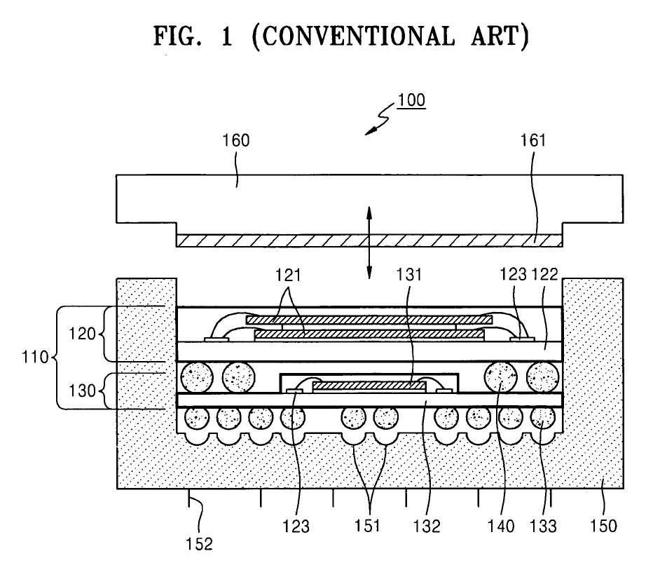

In example embodiments of the present invention, when the multi-stack integrated circuit package 210 is inserted (or placed) into the socket 250 for testing purposes, contact quality of the contact balls 240 may be determined by pulling downward (or positioning) the bottom surface of the lower package 230. In other words, by pulling downward (or positioning) the lower package 230 by applying a vacuum using the vacuum pump 270, contact quality between the internal pins 251 of the socket 250 and the package pins 233 of the multi-stack integrated circuit package 210 may increase. Because pressure is not applied to the upper package 220 (contrary to FIG. 1), contact quality of the contact balls 240 may be determined (and assessed) by a simple signal measurement in a state that is similar to an actual operation state.

When input/output signals of the multi-stack integrated circuit package 210 are measured, an input signal for testing may be applied (or transmitted) from the external PCB 260 through the external pins 253 of the socket 250. The input signal may be transmitted to the integrated circuit chips 221 of the upper package 220 and the integrated circuit chip 231 of the lower package 230. The input signal may be transmitted through the internal pins 251 that may be electrically connected to the external pins 253 of the socket 250 and the package pins 233 of the multi-stack integrated circuit package 210. Thus, the integrated circuit chips 221 and 231 may operate. Also, an output signal (through operation of the integrated circuit chips 221 and 231) may be transmitted to the external PCB 260 through the package pins 233 of the multi-stack integrated circuit package 210 and the external pins 253 of the socket 250. The input/output signals, which are input from and output, respectively, to the external PCB 260, may be measured by signal measurement equipment.

FIG. 4 is a diagram illustrating a contact failure caused by a contact ball.

When the integrated circuit chips 221 and 231 are tested as described in the conventional art, a crack in the contact balls 240 (as shown in FIG. 4), a conductivity failure of a contact face of the upper substrate 222 or the lower substrate 232, or a conductivity failure of the contact balls 240 may occur. As such, the conductivity failure may function as a large resistor according to the conventional methods. Due to the crack or conductivity failure, a signal transmitted from the bad contact ball 240 may not be output as desired. Because a downward pressure is applied to the upper package 220 in a package structure (as shown in FIG. 1), contact quality of the contact ball 240 having a crack may increase and the contact ball 240 may not function as a large resistor. As a result, the real contact quality of the bad contact ball 240 may not be measured accurately.

To facilitate the determination of a contact failure caused by the contact balls, an apparatus for testing a multi-stack integrated circuit package may be used.

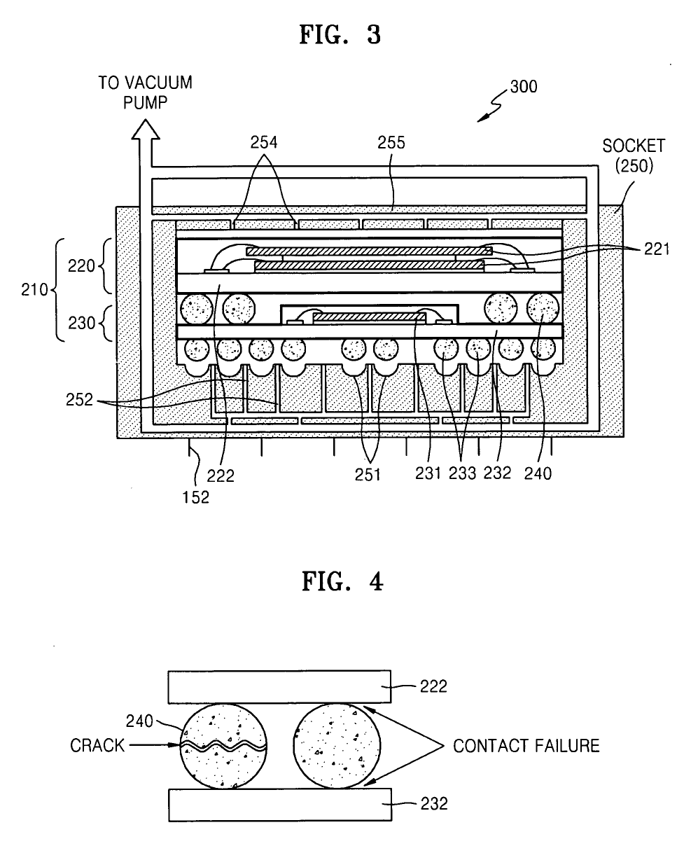

FIG. 3 is a diagram illustrating an apparatus for testing a multi-stack integrated circuit package according to example embodiments of the present invention.

Referring to FIG. 3, the apparatus 300 may be similar to the diagram depicted in FIG. 2, except for the structure of the socket 250. Similar to FIG. 2, the socket 250 of FIG. 3 may include the plurality of internal pins 251, the plurality of external pins 253 that are electrically connected to the internal pins 251 and the at least one first air inlet 252 in communication with the atmosphere between the internal pins 251. The socket 250 of FIG. 3 may also include a cover portion 255 on the upper package 220 and at least one second air inlet 254 in the cover portion 255 through which the air may be removed by the vacuum pump 270 on the upper package 220.

For testing using the socket 250 of FIG. 3, the package pins 233 of the multi-stack integrated circuit package 210 may be inserted (or placed) into the internal pins 251 of the socket 250 and the external pins 253 of the socket 250 may be connected to the external PCB 260.

Before input/output signals of the multi-stack integrated circuit package 210 are measured, the air may be suctioned (or removed) through the first air inlet 252 and the second air inlet 254 of the socket 250 by applying a vacuum using the vacuum pump 270. The bottom surface of the lower package 230 may be pulled downward (or positioned) and the top surface of the upper package 220 may be pulled upward (or positioned) by air suction of the vacuum pump 270.

In example embodiments of the present invention, when the multi-stack integrated circuit package 210 is inserted (or positioned) into the socket 250 for testing purposes, the upper package 220 and the lower package 230 are pulled (or positioned) in opposite directions, more accurately determining contact quality of the contact balls 240. As such, contact quality of the contact balls 240 may increase by pulling downward (or positioning) the lower package 230 using a structure as illustrated in FIG. 2. By pulling (or positioning) the upper package 220 and the lower package 230 in opposite directions using a structure as illustrated in FIG. 3, a crack in the contact balls 240 (as shown in FIG. 4) or a contact failure caused by the contact balls 240 with the upper substrate 222 or the lower substrate 232, may be more accurately measured.

The apparatuses 200 and 300 according to example embodiments of the present invention may more easily determine a contact failure caused by the contact balls 240 between the upper package 220 and the lower package 230 of the multi-stack integrated circuit package by pulling (or positioning) the upper package 220 and the lower package 230 apart (or away) from each other using the vacuum pump 270.

As described above, according to example embodiments of the present invention, a contact failure caused by contact balls that contact upper and lower packages of a multi-stack integrated circuit package may be more easily determined.

The foregoing is illustrative of the example embodiments of the present invention and is not to be construed as limiting thereof. Although example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. An apparatus for testing a multi-stack integrated circuit package, the apparatus comprising:
a vacuum pump, capable of applying a vacuum; and
a socket having a plurality of internal pins, a plurality of external pins that are electrically connected to the plurality of internal pins, and at least one first air inlet in communication with an atmosphere between the plurality of internal pins;
wherein a plurality of package pins of the multi-stack integrated circuit package are inserted into the plurality of internal pins and the multi-stack integrated circuit package is positioned by applying the vacuum through the at least one first air inlet during testing.

2. The apparatus of claim 1, wherein the multi-stack integrated circuit package includes:
an upper package and a lower package, each package of which has at least one integrated circuit chip;
lower input/output pads on the lower package, the lower input/output pads being electrically connected to a substrate of the lower package; and
upper input/output pads on the upper package, the upper input/output pads being electrically connected to a substrate of the upper package;
wherein the substrate of the upper package and the substrate of the lower package are electrically connected by contact balls.

3. The apparatus of claim 2, wherein the plurality of package pins are electrically connected to the contact balls and the lower input/output pads through the substrate of the lower package.

4. The apparatus of claim 2, wherein the lower package is moved by applying the vacuum using the vacuum pump.

5. The apparatus of claim 4, wherein the lower package is moved down by applying the vacuum under the plurality of package pins.

6. The apparatus of claim 2, wherein the socket includes:
a cover portion, positioned on the upper package, including at least one second air inlet through which the vacuum is applied using the vacuum pump.

7. The apparatus of claim 6, wherein the at least one second air inlet is located within the cover portion, and the vacuum pump is connected to the cover portion.

8. The apparatus of claim 6, wherein a bottom surface of the lower package is moved away from a top surface of the upper package by applying the vacuum using the vacuum pump.

9. The apparatus of claim 8, wherein the bottom surface of the lower package is moved away from the top surface of the upper package by applying the vacuum under the plurality of package pins.

10. The apparatus of claim 1, wherein the multi-stack integrated circuit package includes a plurality of packages.

11. The apparatus of claim 1, wherein the multi-stack integrated circuit package includes a switch that initiates the vacuum pump.

12. A socket, comprising:
a plurality of internal pins;
a plurality of external pins that are electrically connected to the plurality of internal pins; and
a socket body including at least one first air inlet in communication with an atmosphere between the plurality of internal pins;
wherein a plurality of package pins of a multi-stack integrated circuit package are positioned into the plurality of internal pins and the multi-stack integrated circuit package is moved by applying vacuum through the at least one first air inlet.

13. The socket of claim 12, wherein the multi-stack integrated circuit package includes:
an upper package and a lower package, each package of which has at least one integrated circuit chip;
lower input/output pads on the lower package, the lower input/output pads being electrically connected to a substrate of the lower package; and
upper input/output pads on the upper package, the upper input/output pads being electrically connected to a substrate of the upper package;
wherein the substrate of the upper package and the substrate of the lower package are electrically connected by contact balls.

14. The socket of claim 12, wherein the socket includes:
a cover portion positioned on the upper package; and
at least one second air inlet through which the vacuum is applied using a vacuum pump.

15. The socket of claim 14, wherein the at least one second air inlet is located within the cover portion, and the vacuum pump is connected to the cover portion.

16. A method for testing a multi-stack integrated circuit package, the method comprising:
inserting a plurality of package pins of the multi-stack integrated circuit package into a plurality of internal pins of a socket;
positioning the multi-stack integrated circuit package by applying vacuum using at least one first air inlet positioned between the internal pins, the at least one first air inlet in communication with an atmosphere below the plurality of package pins;
transmitting an input signal for testing to the multi-stack integrated circuit package from an external printed circuit board (PCB) through a plurality of external pins of the socket that are electrically connected to the plurality of internal pins; and
measuring an output signal from the multi-stack integrated circuit package.

17. The method of claim 16, wherein a vacuum pump is used to apply the vacuum.

18. The method of claim 16, wherein the multi-stack integrated circuit package includes:
an upper package and a lower package, each package of which has at least one integrated circuit chip;
lower input/output pads on the lower package, the lower input/output pads being electrically connected to a substrate of the lower package; and
upper input/output pads on the upper package, the upper input/output pads being electrically connected to a substrate of the upper package;
wherein the substrate of the upper package and the substrate of the lower package are electrically connected by contact balls.

19. The method of claim 18, wherein the plurality of package pins are electrically connected to the contact balls and the lower input/output pads through the substrate of the lower package.

20. The method of claim 18, further comprising moving a bottom surface of the lower package by applying a vacuum under the plurality of package pins.

21. The method of claim 18, wherein positioning the multi-stack integrated circuit package includes applying a vacuum using a vacuum pump through at least one second air inlet in communication with the atmosphere in the cover portion.

22. The method of claim 21, further comprising moving a bottom surface of the lower package away from a top surface of the upper package by applying a vacuum using a vacuum pump.

23. The method of claim 16, wherein the multi-stack integrated circuit package includes a plurality of packages.
